(19) United States
(12) Patent Application Publication
(10) Pub. No.: US 2008/0308874 A1
(43) Pub. Date: Dec. 18, 2008

(54) Complementary Asymmetric High Voltage Devices and Method of Fabrication

(75) Inventors: Theodore Letavic, Putnam Valley, NY (US); Herman Effing, Overasselt (NL); Robert Cook, Poughkeepsie, NY (US)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/910,613

(22) PCT Filed: Mar. 30, 2006
(86) PCT No.: PCT/IB2006/050970

§ 371 Date: Jun. 27, 2008

Related U.S. Application Data
(60) Provisional application No. 60/666,923, filed on Mar. 31, 2005.

(51) Int. Cl. H01L 29/00; H01L 21/8238

(52) U.S. Cl. 257/369; 438/221; 257/E29.001; 257/E21.632

(57) ABSTRACT

An asymmetric semiconductor device (10) and method of forming the same in which 25V devices can be fabricated in processes with gate oxide thicknesses designed for 2.75 or 5.5V maximum operation. The device includes: a shallow trench isolation (STI) region (12) that forms a dielectric between a drain region (18) and a gate region (20) of a unit cell to allow for high voltage operation; and an n-type well (14) and a p-type well (24) patterned within the unit cell.

This application claims priority to co-pending U.S. provisional patent application filed Mar. 31, 2005, Ser. No. 60/666,923, entitled “COMPLEMENTARY ASYMMETRIC HIGH VOLTAGE DEVICES AND METHOD OF FABRICATION,” the contents of which is hereby incorporated by reference.

The invention relates generally to semiconductor device structures, and more particularly, to a semiconductor device structure having a shallow trench isolation (STI) region that forms a dielectric between the drain and the gate.

Currently, conventional lateral diffused metal oxide semiconductor devices (LDMOS) are widely used for power management and automotive integrated circuits. Such a device is described for example in “A Review of RESURF Technology,” Ludikhuize, A. W., Power Semiconductor Devices and ICs, 2000, Proceedings, The 12th International Symposium on 22-25 May 2000, pages 11-18, which is hereby incorporated by reference.

The article discusses the present state-of-the-art design and performance for lateral extended drain or LDMOS device structures. These devices are fabricated in dedicated processes, or are integrated into existing complimentary metal oxide semiconductor (CMOS) type process flows. In these device designs, a drain or drift extension region is formed by growing a thicker field oxide region over a lightly doped drain semiconductor extension. The thicker field oxide region is used to support the drain-gate applied voltage without degrading the gate oxide over the channel region of the MOS device. The doping in the lightly doped drain region is limited by the maximum drain voltage and the robustness of the device in the forward safe operating area and under transient maximum voltage stress. The fabrication of the LDMOS device structure involves the addition of at least two mask levels to the standard CMOS process flow for each type of device fabricated (nchannel and pchannel). The thermal budget needed to grow the thick thermal oxide layer between the drain and gate severely limits the performance of the CMOS components fabricated in the same integrated process flow.

Accordingly, a need exists for an improved CMOS device that can provide a low-cost technology base that can be utilized for mobile power management integrated circuits (PMU) applications.

This invention uses the process modules of deep-submicron CMOS process flows to construct an extended drain high voltage device, rather than designing a high voltage structure and trying to integrate it into an existing process flow. Specifically, the shallow-trench isolation structure of deep-submicron CMOS is used to form the thick dielectric region between the drain and gate of the high voltage device, and the gate oxide and well implants of the CMOS are used to design asymmetric non self-aligned extended drain high voltage devices. One benefit of this is that high voltage devices can be fabricated within existing deep-submicron process flows without additional masks. A single high energy implant mask (e.g., a deep n-well implant) is added to baseline CMOS process flow to provide isolation of the high voltage devices from the substrate and provide depletion charge to shape the breakdown ionization path, which is necessary for some power integrated circuit applications.

Since existing CMOS process modules are used to fabricate high voltage devices, the process complexity of adding a drift doping layer and the thick field oxide region of the conventional approach are removed. This gives both cost and performance benefits, as the baseline deep-submicron process are not perturbed to construct the high voltage components.

In a first aspect, the invention provides an asymmetric CMOS device comprising: a shallow trench isolation (STI) region that forms a dielectric between a drain region and a gate region of a unit cell to allow for high voltage operation; and an n-type well and a p-type well patterned within the unit cell.

In a second aspect, the invention provides a method of forming an asymmetric CMOS device, comprising: forming a deep well implant of a first type; forming a first well implant of the first type above the deep well implant and below a drain region and a portion of a gate region; forming a shallow trench isolation (STI) region in the first well implant below a portion of the gate location adjacent the drain location; and forming a second well implant of a second type below a source region.

In a third aspect, the invention provides a method of forming an asymmetric CMOS device, comprising: forming a deep well implant of a first type above an epitaxial layer and substrate layer; forming a first well implant of the first type patterned below a drain region and a portion of a gate region; forming a second well implant of a second type patterned below a source region; forming a shallow trench isolation (STI) region between the drain region and a gate region of a unit cell to allow for high voltage operation; and wherein the device is fabricated using a baseline CMOS flow selected from the group consisting of: a 5 volt baseline CMOS flow in which in which a gate oxide thickness of approximately 12.3-15.0 nm is utilized and the first and second well implants comprise a high voltage p-well implant and an high voltage n-well implant, and a 2.5 volt baseline CMOS process flow in which a gate oxide thickness of approximately 5.0-5.4 nm is utilized and the first and second well implants comprise an n-type well (NW) and p-type well (PW).

A feature of this invention is that the STI region can be incorporated into the active unit cell of a transistor, rather than just using it for isolation of the CMOS. An additional new insight is that the scaled CMOS process modules can be used to form the channel and extended drain region of much higher voltage transistors without adding extra masks to the process. The 2D layout of the high voltage design provides for robust high voltage performance, a significant amount of intellectual property exists in the specific layout design and optimization of the CMOS baseline STI module. Complementary high voltage devices are easily obtained by using the NMOS and PMOS baseline CMOS process modules, with matching threshold voltage characteristics.

These and other features of this invention will be more readily understood from the following detailed description of the various aspects of the invention taken in conjunction with the accompanying drawings in which:

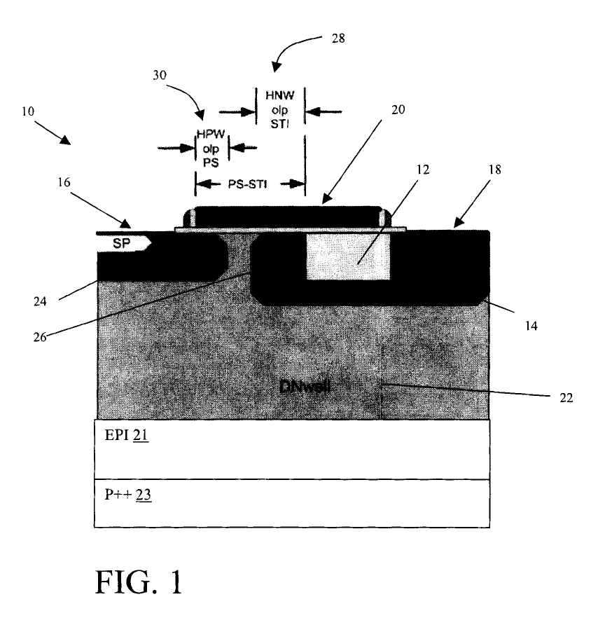

FIG. 1 depicts a cross-sectional layout of an asymmetric high voltage device integrated into a 5 volt CMOS process having a Shallow Trench Isolation (STI) region fabricated between the drain and the gate of a unit cell in accordance with an embodiment the present invention.

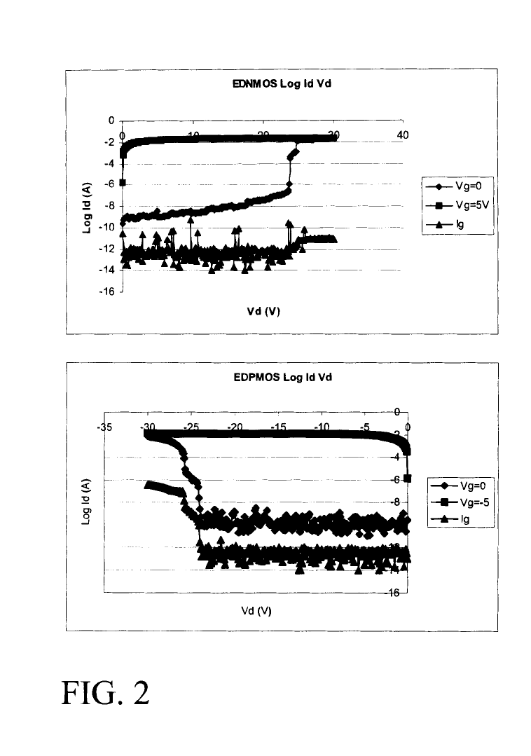

FIG. 2 depict simulations of impact ionization as a function of drain bias for the device of FIG. 1.

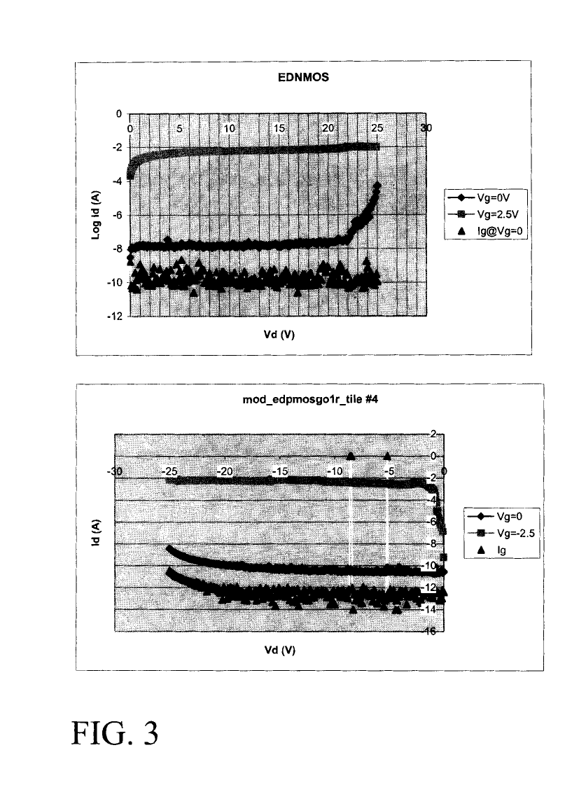

FIG. 3 depicts measured current/voltage (IV) characteristics and blocking voltage characteristics for complementary EDMOS devices fabricated with either the 5V or 2.5V baseline CMOS modules.

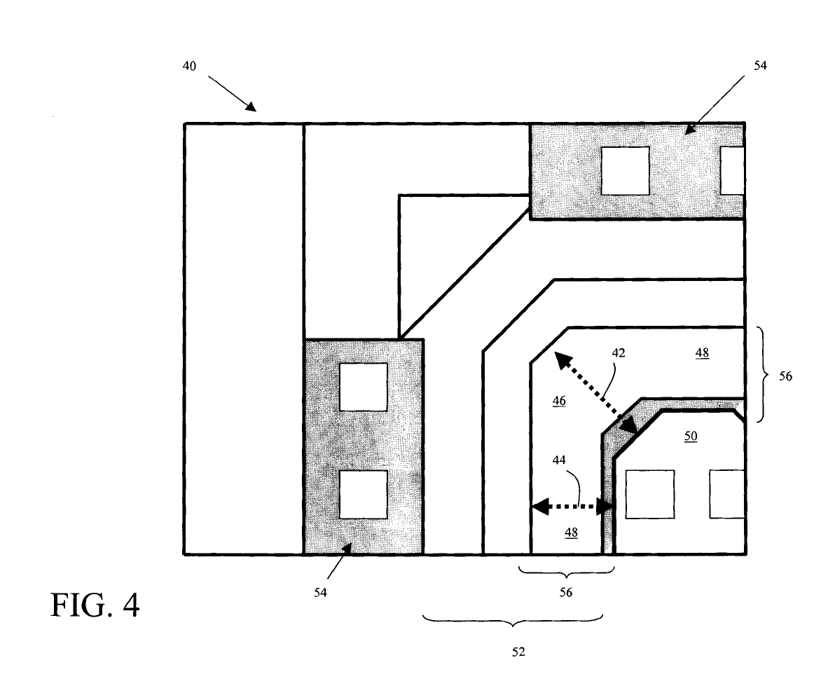

FIG. 4 depicts a surface layout having a ring like structure in accordance with an embodiment the present invention.

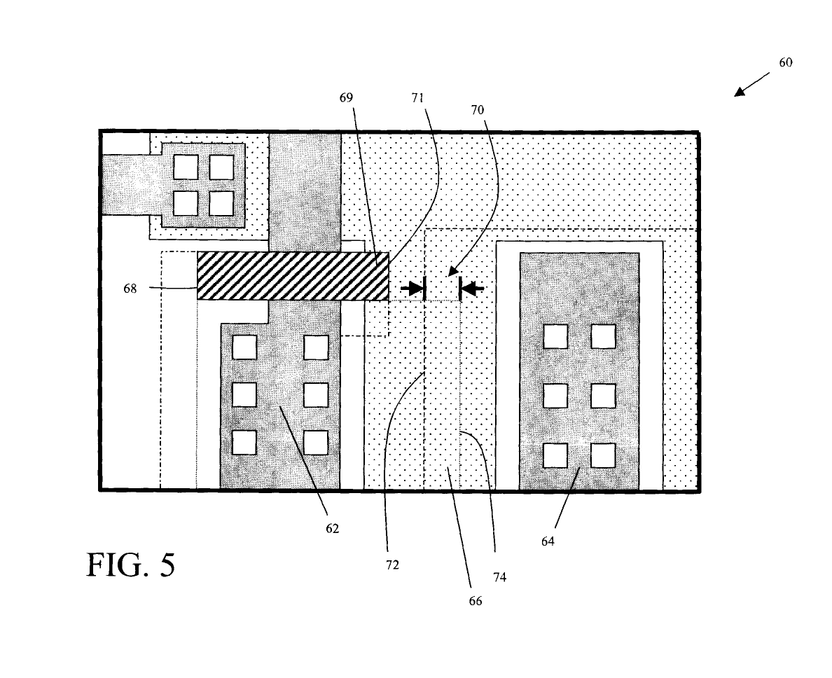

FIG. 5 depicts a surface layout having a linear structure in accordance with an embodiment the present invention.

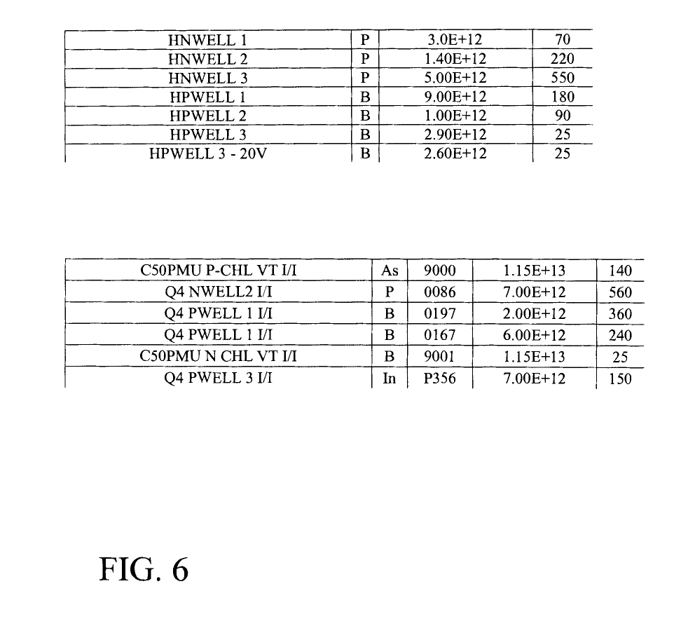

FIG. 6 depicts retrograde well tables for 5V and 2.5V devices, respectively, in accordance with an embodiment the present invention.

This embodiments described herein provide a new semiconductor device in the field of high-voltage CMOS or extended drain high voltage devices. A design and process technique is specified to significantly increase the breakdown voltage of complementary NMOS and PMOS devices by providing a thick dielectric region between the gate and drain of the devices. The dielectric is added without extra process steps since a Shallow Trench Isolation (STI) process module is used. The result is that >25V devices can be fabricated in processes with gate oxide thicknesses designed for 2.75 or 5.5V maximum operation. This provides a low-cost technology base that can be utilized for such application as mobile power management integrated circuits (PMU) applications.

FIG. 1 depicts a cross-section of an extended drain nchannel device (EDNMOS) 10 that is fabricated such that a shallow trench isolation region (STI) 12 is formed within the unit cell of the device structure. The STI 12 forms a thick dielectric region between the drain region 18 and gate region 20 that can support voltages much higher than what the baseline CMOS process flow is designed for.

The illustrative device 10 includes a DNwell (deep n-well implant) layer 22, an HPW (high voltage p-well implant) layer 24 beneath the source region 16, and an HNW (high voltage n-well implant) layer 14 beneath the drain region 18 and a portion of the gate region 20. In this case, the STI 12 sits within the HNW layer 30 and forms a thick dielectric region between the drain 18 and source 16. An extended drain pchannel device could be implemented simply by reversing the wells, i.e., using the low-voltage PMOS process modules to form the extended drain PMOS (EDPMOS). Beneath the DNwell layer 22 is an epitaxial (EPI) layer 21 and a Pa substrate 23.

Presently there are two well and gate oxide thicknesses that are available to fabricate the high voltage transistor:

Gate oxide 1 (GO1)=approximately 5.0-5.4 nm thick with the 2.5V (retrograde) wells, high voltage p-well implant (HPW) and an high voltage n-well implant (HNW); or

Gate oxide 2 (GO2)=approximately 12.3-15.0 nm thick with the 5V (retrograde) wells, p-well implant (PW) and n-well implant (NW).

Device 10 in FIG. 1 is fabricated using the 5V CMOS process modules of the baseline CMOS flow (i.e., GO2). HPW 24 is channel diffused for 5V NMOS, and HNW 14 is channel diffused for 5V PMOS. The 2.5V modules can be used as well, replacing the HNW 14 with NW and HPW 24 with PW and using the thin GO1 gate oxide. EDMOS devices fabricated with either GO1 or GO2 can block voltages over 25V, much higher than the baseline transistors are designed for.

As can be seen, the polysilicon gate region 20 extends over the STI 12, allowing the thick STI dielectric to support drain-gate voltage. This breaks the standard scaling rule of gate oxide thickness to application voltage. An important design parameter, which defines the breakdown voltage of extended drain devices, is the overlap 28 of the drain extension photoresist mask (i.e., the region formed by HNW 14) on the STI edge 26. The HNW charge separates the heavily doped drain region 18 from the channel region of the device region 24. In many cases, optimum performance is obtained by having the overlap distance 28 be negative, i.e., the drain extension photoresist mask is pulled away from the STI edge 26, leaving the STI 12 to block almost all of the (retrograde) well charge that is implanted, leaving only the implant lateral straggle to define the drain extension dose.

Additional important layout parameters that define the BVds (breakdown voltage) of the device are as follows. The mask overlap or underlap “HNW olp STI” 28 of HNW 14 over STI 12 for the EDNMOS device 10 is very important, as is HPW over STI 12 for the EDPMOS device (not shown). The HPW 24 overlap of the polysilicon gate region 20 “HWP olp PS” 30 should be set large enough to give the same on-state threshold voltage

(Vto) as the corresponding NMOS component (HNW for the PMOS). Vto is determined by the total amount of charge in the HPW region 24. Since it is mask defined, the overlap 30 has to be large enough to give full surface concentration to get the same threshold voltage as the lower voltage wells it is derived from.

FIG. 2 and FIG. 3 show measured current/voltage (IV) characteristics and blocking voltage characteristics for complementary EDMOS devices fabricated with either the 5V or 2.5V baseline CMOS modules, all with the STI layer 12 juxtaposed between the gate region 20 and drain 18 region. An additional benefit of this device construction is that the drain resistance along the STI sidewall improves the forward SOA (safe operating area) and ESD (electrostatic discharge) ruggedness of the device 10 by providing a ballasting resistance intrinsic to the device 10.

In FIG. 2, it can be seen that the measured IV curves for GO2 EDMOS devices show BVds=25V and a good forward safe operating area. Likewise in FIG. 2, it can be seen that the measured IV curves for GO1 EDMOS devices show BVds=25V and a good forward safe operating area.

FIG. 2 and FIG. 3 show experimental results that this design technique can be used to fabricate devices with high enough voltage handling (25V) to include the power management function into a baseline CMOS process flow. These figures are the result of extensive process and device simulations to define the optimal layout and design of these extended drain structures, and finally constructing these devices within an integrated process flow to prove the concepts. These devices also contain an extra implant deep NW (DNwell 22), which isolates the extended drain from the substrate. The devices are designed so that the lateral breakdown is lower than the vertical breakdown.

The device simulations indicate that the 2D layout completely defines the behavior of these components, as layout is the only degree of freedom as the 2.5V and 5V process modules cannot be altered as the performance of the baseline 2.5 and 5V components has to be guaranteed.

The 2D surface layout of the device 10 is also important to maintain high voltage (i.e., 25V) capability in a process that is designed only for low voltage (<5V). In one illustrative embodiment, robust high voltage performance is obtained when the 2D layout of the transistor from the surface is in a ring shape, with the STI width in the cylindrical regions being wider than in the linear regions. An example is shown in FIG. 4 in which an upper left hand corner of a ring-shaped device 40 is shown. In the lower right corner (i.e., the center of the ring) is the drain region 50, which is surrounded by the polysilicon gate region 52. Further out in the ring is a source region 54. The STI region 56 forms a ring around drain region 50 below an inner portion of the gate region 52. STI region 56 includes linear regions 48 and cylindrical regions 46. In this embodiment, the STI width 42 in the cylindrical region 46 is approximately 1.5 times the STI width 44 in the linear region 48. This relaxes the electric field in the cylindrical region 46 and avoids punchthrough depletion.

FIG. 5 depicts an illustrative embodiment of a surface layout of an EDNMOS device 60 having a linear 2D layout, which also provides reduced high voltage leakage. In this case, the gate region 66 is located between the source region 62 and the drain region 64. In device 60, the p+body contact (defined by width 68) is pulled up to the gate edge to form a deactivated source region 69 to inactivate the source 62 along the edge of the transistor. This arrangement provides better high voltage performance, i.e., reduces high voltage leakage and channel punchthrough current. FIG. 5 also shows the overlap 70 of the HNW 72 over the STI 74 for the drain extension. This is a positive overlap 70, whereas a negative overlap may give better performance.

Illustrative doses and material parameters to form such a device are as follows. The P++ substrate 23 may be fabricated with about a 4 um-thick p−− epitiaxial layer 21 (FIG. 1). A GO1 oxide thickness of about 5.0-5.4 nm or a GO2 oxide thickness of about 12.3-15 nm may be utilized. An STI 12 may have about a depth of 0.35-0.45 um. FIG. 6 depicts illustrative retrograde well tables for 5V and 2.5V components including species, dose, and energy. Both the n-type and p-type well implants are patterned within the device unit cell to form source and drain contacts. The device may, for example, include a DNWell implant ˜1-2 MeV 5e12 cm-2 31 Phos for substrate isolation and a DPWell implant of 500-700 keV 1e13 cm-2 11B for deep isolation (wherein 31 Phos and 11B are implant species, i.e., phosphorus and boron for n-type and p-type doping, respectively).

The steps involved in the fabrication processes, are essentially as follows:

(1) form a deep well implant 22 of a first type above an epitaxial layer and substrate layer;
(2) form a first well implant 14 of the first type patterned below the drain region 18 and a portion of the gate region 20;
(3) form a second well implant 24 of a second type patterned below the source region 16;
(4) form a shallow trench isolation (STI) region 12 in the first well implant 14 between the drain region 18 and the gate region 20 to allow for high voltage operation; and
(5) wherein the device is fabricated using a baseline complimentary metal oxide semiconductor (CMOS) flow selected from the group consisting of:

(a) a 5 volt baseline CMOS flow in which in which a gate oxide thickness of approximately 12.3-15.0 nm is utilized and the first and second well implants comprise a high voltage p-well implant (24) and an high voltage n-well implant (14), and

(b) a 2.5 volt baseline CMOS process flow in which a gate oxide thickness of approximately 5.0-5.4 nm is utilized and the first and second well implants comprise an n-type well (NW) and p-type well (PW).

Note that asymmetric complementary devices are enhancement mode devices, meaning there is no current flow at zero gate-source voltage by design. This can be contrasted with depletion mode devices, in which there is current flow at zero gate-source voltage. Moreover, depletion mode construction is obtained by intentionally overlapping of the NW and PW implants to form a compensated channel region, whereas enhancement mode devices forbid overlap of NW and PW in the channel region by definition.

The foregoing description of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of this invention as defined by the accompanying claims.

1. An asymmetric complementary metal oxide semiconductor (CMOS) device comprising: a shallow trench isolation (STI) region that forms a dielectric between a drain region and a gate region of a unit cell to allow for high voltage operation; and an n-type well and a p-type well patterned within the unit cell.

2. The asymmetric semiconductor device of claim 1, further comprising a deep N-Wel implant that provides substrate isolation, wherein the deep N-Well implant is at an energy of about 1-2MeV and a dose of about 5×10¹² cm⁻² of Phosphorus-31 (31 Phos).

3. The asymmetric semiconductor device of claim 1, wherein the drain region includes an extended drain overlap of the STI region that is negative.

4. The asymmetric semiconductor device of claim 1, further comprising a surface layout that is substantially shaped as a ring, wherein the drain region is located at a center of the ring and the STI region is located around the drain region.

5. The asymmetric semiconductor device of claim 4, wherein the STI region includes a linear portion and a cylindrical portion, and wherein the cylindrical portion is at least 1.2 times the width of the linear portion.

6. The asymmetric semiconductor device of claim 1, further comprising a surface layout that is substantially linear in nature that includes a deactivated source region disposed along a device edge of the surface layout.

7. The asymmetric semiconductor device of claim 1, wherein the device is one of either an extended drain n-type metal oxide (EDNMOS) or an extended drain p-type metal oxide (EDPMOS) device.

8. The asymmetric semiconductor device of claim 1, wherein the device is formed using a 5 volt baseline complementary metal oxide (CMOS) process flow in which a gate oxide thickness of approximately 12.3-15.0 nm is utilized and the first and second well implants comprise a high voltage p-well implant and an high voltage n-well implant.

9. The asymmetric semiconductor device of claim 1, wherein the device is formed using a 2.5 volt baseline complimentary metal oxide (CMOS) process flow in which a gate oxide thickness of approximately 5.0-5.4 nm is utilized and the first and second well implants comprise an n-type well (NW) and a p-type well (PW).

10. A method of forming an asymmetric complimentary metal oxide semiconductor (CMOS) device, comprising: forming a deep well implant of a first type; forming a first well implant of the first type above the deep well implant and below a drain region and a portion of a gate region; forming a shallow trench isolation (STI) region in the first well implant below a portion of the gate location adjacent the drain location; and forming a second well implant of a second type below a source region.

11. The method of claim 10, wherein the STI region is approximately 0.35-0.45 pm thick.

12. The method of claim 10, wherein the device is formed using a 5 volt baseline complimentary metal oxide (CMOS) process flow in which a gate oxide thickness of approximately 12.3-15.0 nm is utilized and the first and second well implants comprise a high voltage p-well implant and an high voltage n-well implanted.

13. The method of claim 10, wherein the device is formed using a 2.5 volt baseline complimentary metal oxide (CMOS) process flow in which a gate oxide thickness of approximately 5.0-5.4 nm is utilized and the first and second well implants comprise an n-type well (NW) and p-type well (PW).

14. The method of claim 10, wherein the deep well implant is formed using at an energy of about 1-2 Me and a dose of about 5×10¹² cm⁻² of Phosphorus-31 (31 Phos) to provide substrate isolation.

15. The method of claim 10, wherein the drain region includes an extended drain overlap of the STI region that is negative.

16. The method of claim 10, wherein a surface layout of the device is substantially formed as a ring, wherein the drain region is located at a center of the ring and the STI region is located around the drain region.

17. The method of claim 16, wherein the STI region includes a linear portion and a cylindrical portion, and wherein the cylindrical portion is at least 1.2 times the width of the linear portion.

18. The method of claim 10, wherein a surface layout of the device is substantially linear in nature and includes a deactivated source region disposed along a device edge of the surface layout.

19. The method of claim 10, wherein the device is one of either an extended drain n-type metal oxide (EDNMOS) or an extended drain p-type metal oxide (EDPMOS) device.

20. A method of forming an asymmetric complimentary metal oxide semiconductor (CMOS) device, comprising: forming a deep well implant of a first type above an epitaxial layer and substrate layer; forming a first well implant of the first type patterned below a drain region is and a portion of a gate region; forming a second well implant of a second type patterned below a source region; forming a shallow trench isolation (STI) region in the first well implant between the drain region and a gate region to allow for high voltage operation; and wherein the device is fabricated using a baseline CMOS flow selected from the group consisting of: a 5 volt baseline CMOS flow in which in which a gate oxide thickness of approximately 12.3-15.0 nm is utilized and the first and second well implants comprise a high voltage p-well implant and an high voltage n-well implanted and a 2.5 volt baseline CMOS process flow in which a gate oxide thickness of approximately 5.0-5.4 nm is utilized and the first and second well implants comprise an n-type well (NW) and p-type well (PW).
